(19) United States
(12) Patent Application Publication
(10) Pub. No.: US 2006/0097279 A1
(43) Pub. Date: May 11, 2006

(54) Three-Dimensional Memory System-on-a-Chip

(76) Inventor: Guobiao Zhang, Stateline, NV (US)

Correspondence Address: Dr.Guobiao Zhang, P.O. Box 6182, Stateline, NV, 89449-6182, US

(21) Appl. No.: 11/163,889

(22) Filed: Nov. 2, 2005

(30) Foreign Application Priority Data
Nov. 5, 2004 (CN) 200410040968.3

(51) Int. Cl. H01L 29/74

(52) U.S. Cl. 257/120

(57) ABSTRACT

The present invention discloses a three-dimensional memory (3D-M) system-on-a-chip (3DM-SoC) with half-3DM level(s), whose un-used space above the embedded memory is converted into 3D-M level(s). This conversion process, incurring little extra manufacturing cost, can significantly increase the SoC storage capacity. The present invention further discloses a 3DM-SoC with large basic array(s). With large basic arrays, the previously-designed IP blocks could be easily ported over and re-used, thus simplifying the 3DM-SoC design.

### CROSS-REFRENCE TO RELATED APPLICATION

This application is related to a CHINA P. R., patent application, “Three-Dimensional Memory System-on-a-Chip”, Ser. No. 200410040968.3, filed on Nov. 5, 2004.

### BACKGROUND

1. Technical Field of the Invention

The present invention relates to the field of integrated circuits, and more particularly to three-dimensional memory system-on-a-chip (3DM-SoC).

2. Prior Arts

Integrated-circuit (IC) technologies are making rapid advancement. An IC can perform different functions, such as data storage (i.e. memory) and data processing (i.e. processor). Because both memory and processor are based on transistors 1t (which are built in semiconductor substrate, see FIG. 1B), they can be integrated in the same piece of substrate. This is the basis for system-on-a-chip (SoC). A typical SoC chip comprises an embedded memory (eM) 0EM and an embedded uP (eP) 0EP (FIG. 1A). The eM 0EM stores data and comprises RAM and/or ROM. The eP 0EP processes data and comprises logic and/or analog circuits.

In a typical SoC chip, the eM needs far fewer interconnect-levels than the eP. As is illustrated in FIG. 1B, the eP 0EP in the SoC chip 0SOC uses four interconnect-levels 1EP (i.e. IL1-IL4). However, the eM 0EM uses only two interconnect-levels 1EM (i.e. IL1, IL2). As a result, two interconnect-levels (i.e. IL3, IL4) in the eM region 0EM are not used and filled with dummy metals 30d, 40d. Because the eM region 0EM could occupy as much as ˜50% chip area, there is a large un-used space 1DY in the SoC chip. To fully utilize this un-used space 1DY, the present invention discloses a three-dimensional memory (3D-M or 3DM) system-on-a-chip (3DM-SoC) with half-3DM level(s). The half-3DM levels are converted from the un-used space 1DY, and cover only a portion of the 3DM-SoC chip (e.g. the eM region), but not another portion of the 3DM-SoC chip (e.g. the eP region). This conversion process, incurring little extra manufacturing cost, can significantly increase the SoC storage capacity and therefore, improve its functionality.

The conventional 3D-M typically uses small basic arrays. As is illustrated in FIG. 16A, this 3D-M 00a comprises a large number (e.g. 4×4=16) of small basic arrays (03A, 03B, 03C . . . ). In each basic array (e.g. 03A of FIG. 16B), its array-substrate-circuit 05A (i.e. substrate circuit underneath a basic array) is surrounded on all sides by its array-peripheral-circuit 04A1-04A4 (i.e. peripheral circuit of a basic array, e.g. decoder, sense-amp) and no portion of the array-substrate-circuit is used as the array-peripheral-circuit. Usage of small basic-arrays could pose a serious problem for system integration, because the 3D-M IC function (i.e. IC function to be integrated with the 3D-M) has to be split and laid-out into several array-substrate-circuits (e.g. into 05A, 05B of FIG. 16B). This means the previously-designed IP blocks could not be ported over and re-used. To overcome this difficulty, the present invention discloses a 3DM-SoC with large basic array(s). Each of its array-substrate-circuit(s) can implement a complete IC function, e.g. audio-processing, video-processing, digital-to-analog converting, or decryption functions.

### OBJECTS AND ADVANTAGES

It is a principle object of the present invention to increase the storage capacity of an SoC chip without incurring extra chip area.

It is a further object of the present invention to improve the functionality of an SoC chip without incurring extra manufacturing cost.

It is a further object of the present invention to re-use the previously-designed IP blocks for the 3D-M IC function.

It is a further object of the present invention to simplify the 3DM-SoC design.

In accordance with these and other objects of the present invention, several preferred 3DM-SoC's are disclosed.

### SUMMARY OF THE INVENTION

The present invention discloses a 3DM-SoC with half-3DM level(s). An SoC chip comprises transistor-based eP and eM. Because the number of interconnect-levels required by the eP is larger than the eM, a number of interconnect-levels on top of the eM region are not used and form an un-used space. This un-used space can be converted into 3D-M level(s). Because this 3D-M level covers only the eM region not the eP region, it is referred to as half-3DM level. This conversion process, incurring little extra manufacturing cost, can significantly increase the SoC storage capacity and therefore, improve its functionality.

The present invention further discloses a 3DM-SoC with large basic array(s). If a 3D-M uses small basic arrays, the 3D-M IC function (i.e. IC function to be integrated with the 3D-M) has to be split and laid-out into several array-substrate-circuits (in each basic array of a 3D-M, its array-substrate-circuit is surrounded on all sides by its array-peripheral-circuit and no portion of the array-substrate-circuit is used as the array-peripheral-circuit). This means the previously-designed IP blocks could not be ported over and re-used. With large basic arrays, each of array-substrate-circuit(s) can implement a complete IC function, e.g. audio-processing, video-processing, digital-to-analog converting, or decryption functions. As a result, the previously-designed IP blocks can be simply ported over and re-used, thus simplifying the 3DM-SoC design.

### BRIEF DESCRIPTION OF THE DRAWINGS

FIG. 1A is a top view of a prior-art SoC chip; FIG. 1B is its cross-sectional view along the cut-line AA;

FIG. 2 is a cross-sectional view of a 3D-M whose 3D-M level covers the whole chip;

FIG. 3 is a cross-sectional view of a preferred 3DM-SoC with a half-3DM level;

FIG. 4 illustrates a first preferred 3D-M/interconnect;

FIGS. 5A-5E illustrates a preferred manufacturing process for the first preferred 3D-M/interconnect;

FIG. 6 illustrates a preferred 3DM-SoC based on electrically-programmable 3D-M (EP-3DM);

FIGS. 7A-7C illustrates several preferred 3D-M layers;

FIG. 8 illustrates a second preferred 3D-M/interconnect;

FIGS. 9A-9C illustrate a preferred manufacturing process for the second preferred 3D-M/interconnect;

FIG. 10 illustrates a third preferred 3D-M/interconnect;

FIGS. 11A-11D illustrate a preferred manufacturing process for the third preferred 3D-M/interconnect;

FIG. 12 illustrates a fourth preferred 3D-M/interconnect;

FIGS. 13A-13D illustrate a preferred manufacturing process for the fourth preferred 3D-M/interconnect;

FIGS. 14A-14CB illustrate a preferred hybrid-interconnect and two preferred manufacturing processes;

FIG. 15 illustrates a preferred 3DM-SoC with half-3DM and full-3DM levels;

FIG. 16A is the layout of a prior-art 3D-M; FIG. 16B is the detailed layout of the prior-art 3D-M;

FIG. 17 is a top view of a preferred 3D-M with large basic array(s).

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

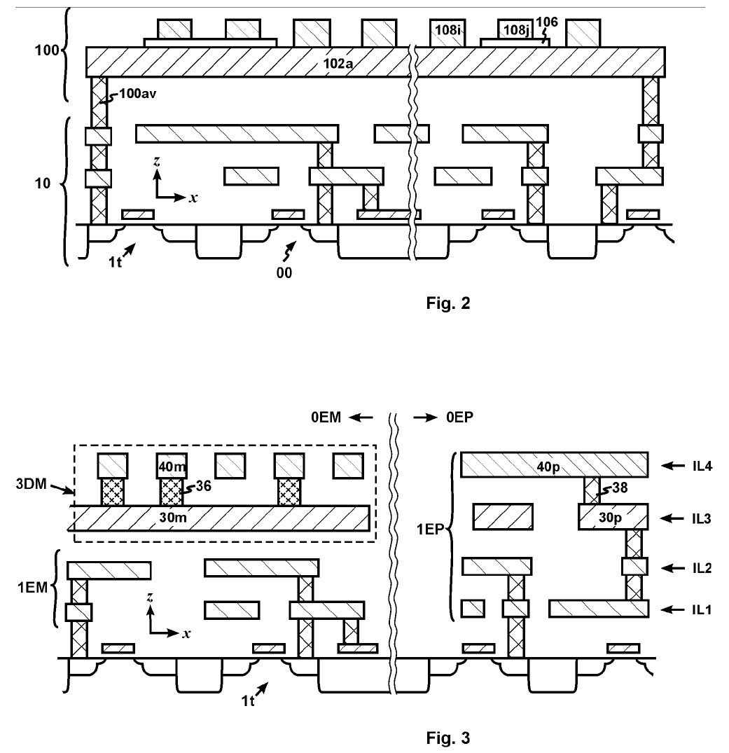

Three-dimensional memory (3D-M) stacks one or more memory levels on top of each other (referring to U.S. Pat. Nos. 5,835,396, 6,717,222). As is illustrated in FIG. 2, this 3D-M comprises at least one (preferably two) 3D-M levels 100. It stacks on top of the substrate circuit 10. The 3D-M level 100 comprises a number of address-selection lines (including word line 102a and bit lines 108i, 108j) and 3D-M cells between word and bit lines. Inter-level vias 100a provides electrical contact between 3D-M level 100 and substrate circuit 10.

A 3D-M can be categorized by its programming means (referring to U.S. Pat. No. 6,717,222): if electrical means is used, this 3D-M is referred to as electrically-programmable 3D-M (EP-3DM); if non-electrical means is used, the 3D-M is referred to as non-electrically-programmable 3D-M (NEP-3DM). EP-3DM further comprises 3D-RAM, 3D-OTP (one-time-programmable), 3D-WM (write-many-times). On the other hand, a typical NEP-3DM is 3D-MPROM (mask-programmable ROM). The 3D-M in FIG. 2 is a 3D-MPROM and it denotes logic “0” or “1” through existence or absence of the insulating dielectric 106.

A 3D-M can also be categorized like a conventional semiconductor memory. Namely, it can be categorized in to 3D-RAM and 3D-ROM (including 3D-MPROM, 3D-OTP and 3D-WM). In the present invention, these two categorizations are interchangeably used.

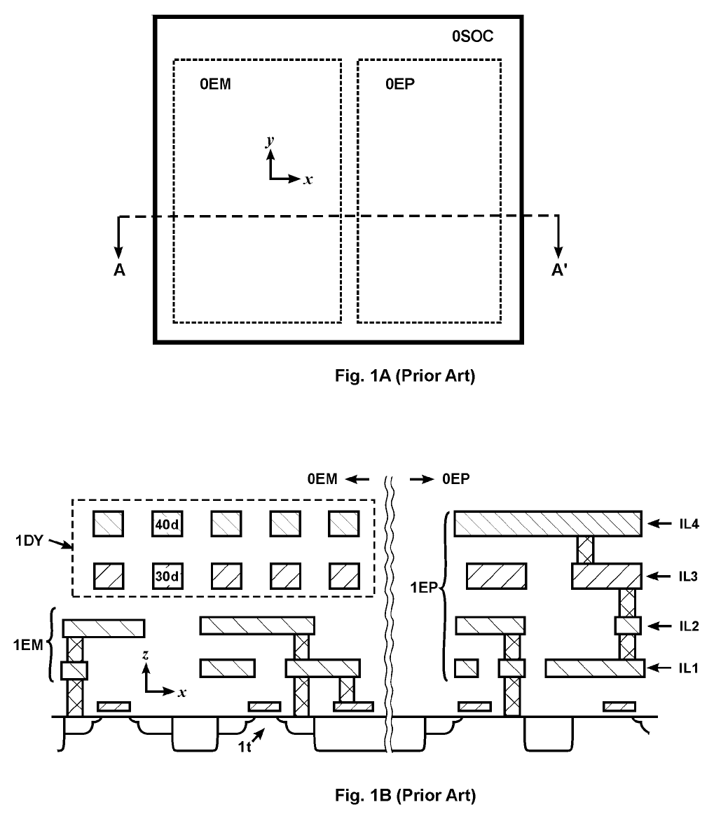

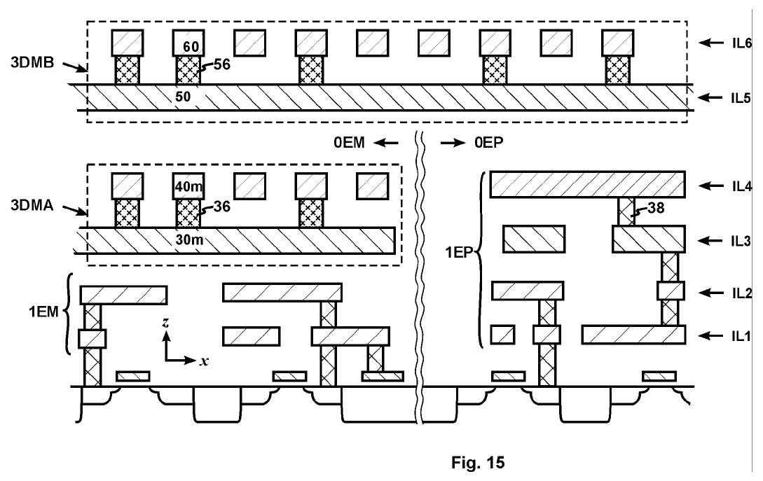

FIG. 3 is a cross-sectional view of a preferred 3DM-SoC with half-3DM level(s). In this preferred embodiment, the un-used space 1DY in FIG. 1B is converted in to a 3D-M level 3DM. Because this 3D-M level only covers the eM region 0EM, not the whole chip, it is referred to as a half-3DM level (in comparison, the 3D-M level 3DMB of FIG. 15 covers the whole chip and therefore, is referred to as a full-3DM level). In the half-3DM 3DM, the interconnect-level IL3 comprises word line 30m; the interconnect-level IL4 comprises bit line 40m; and a 3D-M layer 36 exists between word and bit lines. This 3D-M layer 36 comprises diode-layer (e.g. p-n diode, p-i-n diode, Schottky diode) or other active devices (referring to U.S. Pat. No. 6,717,222).

In this preferred embodiment, the difference in the number of interconnect-levels between the eP and eM is 2 (=4−2). Accordingly, one 3D-M level can be built in the un-used space 1DY. If this difference is 6, then three (assuming separate 3D-M structure is used, referring to FIG. 9 of U.S. Pat. No. 6,717,222) to five 3D-M levels (assuming interleaved 3D-M structure is used, referring to FIG. 10 of U.S. Pat. No. 6,717,222) can be built.

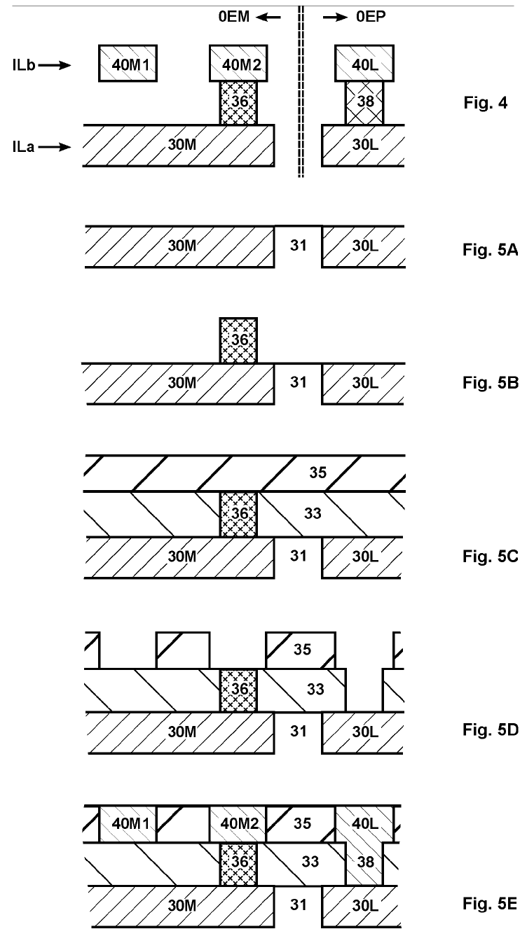

FIG. 4 illustrates a first preferred 3D-M/interconnect between two interconnect-levels ILa (including lower-level conductor 30L, 30M), ILb (including upper-level conductor 40L, 40M1, 40M2). Here, 3D-M/interconnect comprises two types of inter-level connection: 1) 3D-M layer 36 in the eM 0EM, which provides uni-directional electrical conduction; 2) via 38 in the eP region 0EP, which provides bi-directional electrical conduction. Note the two conductors (30L, 40L) in the eP region 0EP are respectively located at the same levels as two address-selection lines (30M, 40M2) in the eM region 0EM. To be more specific, the upper conductor 40L is located at the same level as the upper address-selection line 40M2; the lower conductor 30L is located at the same level as the lower address-selection line 30M.

FIGS. 5A-5E illustrates a preferred manufacturing process for the first preferred 3D-M/interconnect. Compared with the conventional dual-damascene process, it requires only one extra masking step (FIG. 5B), thus incurring little extra manufacturing cost. It comprises the following steps:

1) Form a lower-level conductor ILa using methods such as damascene. These lower-level conductors 30L, 30M are separated by an intra-level dielectric 31 (FIG. 5A);

2) Deposit and etch the 3D-M layer. After this step, 3D-M pillar 36 is formed at the “1” cell in the eM region 0EM (FIG. 5B);

3) Deposit, planarize and etch an inter-level dielectric 33 until the 3D-M pillar 36 in the eM region 0EM is exposed. Then deposit another intra-level dielectric 35 (FIG. 5C). The material and structure of the intra- and inter-level dielectrics 33, 35 are similar to those used in dual damascene;

4) Etch via and trench until: a) in the eM region 0EM, the top surface of the 3D-M pillar 36 is exposed; b) in the eP region 0EP, the top surface of the lower-level conductor 30L is exposed (FIG. 5D). This step is similar to dual damascene;

5) using methods such as CMP, deposit and planarize the upper-level conductor ILb (FIG. 5E). This step is similar to dual damascene.

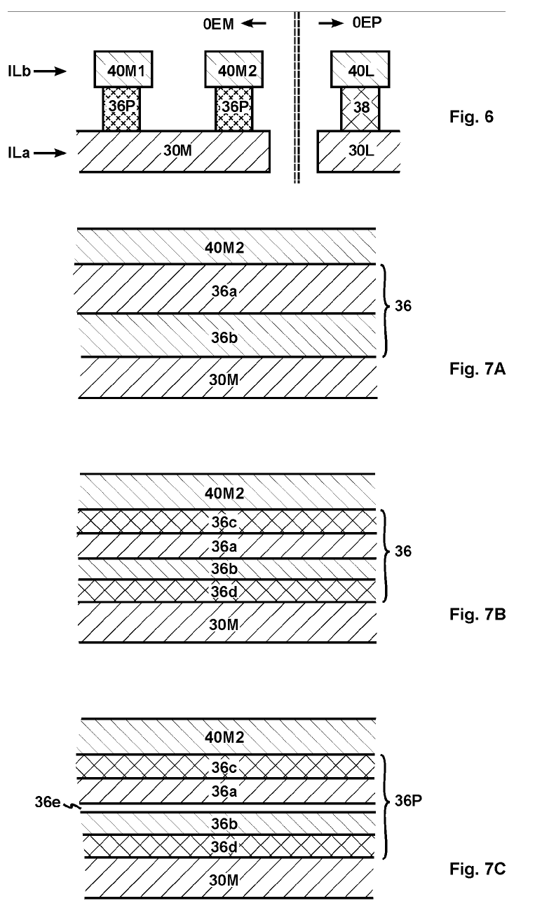

FIGS. 4-5E use 3D-MPROM as an example. On the other hand, FIG. 6 uses EP-3DM as an example. The difference between EP-3DM and 3D-MPROM is that EP-3DM does not require selective removal of the 3D-M layer. Thus, a 3D-M layer 36P is formed at every cell location. The 3D-M layer 36P can comprise diode-antifuse layer, or other active devices. Although most preferred embodiments in the present invention are illustrated as 3D-MPROM, its spirit can be easily extended to other 3D-M (e.g. EP-3DM).

FIGS. 7A-7C illustrate several preferred 3D-M layers. In FIG. 7A, the 3D-M layer 36 comprises a p-layer 36a and an n-layer 36b. It could further comprise an i-layer between the p-layer 36a and n-layer 36p. This i-layer could be lightly-doped. The 3D-M layer 36 in FIG. 7B further comprises a bottom buffer layer 36d and a top buffer layer 36c. These buffer layers 36c, 36d comprise conductive materials, e.g. TiW, W, Cu or heavily-doped semiconductor material. They can be formed at the same time as the p-layer 36a and n-layer 36b. The bottom buffer layer 36d can prevent the defects on the bottom conductor 39M from damaging the n-layer 36b. The top buffer layer 36c can protect the p-layer 36a when the intra-level dielectric c35 is etched. The 3D-M layer 36P in FIG. 7C further comprises an antifuse layer 36e. It can be used in EP-3DM. For those skilled in the art, the 3D-M layer illustrated in FIGS. 7A-7C only represents a small portion of possible 3D-M layers (referring to U.S. Pat. Nos. 5,835,396, 6,717,222).

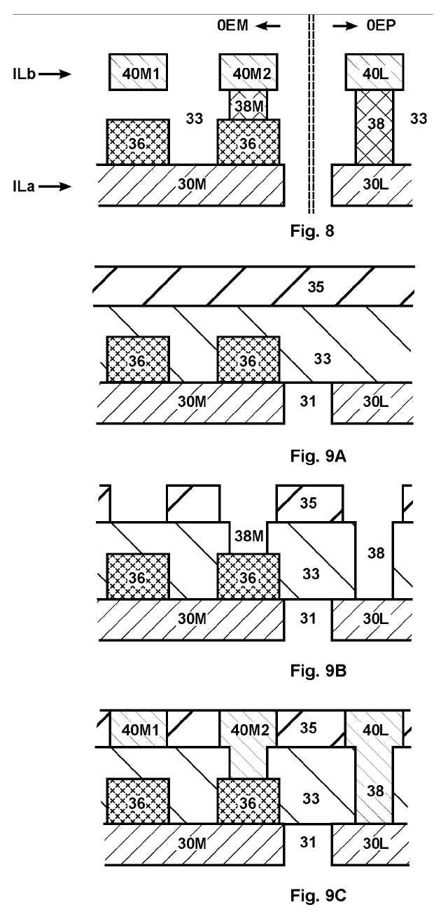

FIG. 8 illustrates a second preferred 3D-M/interconnect. Its only difference with FIG. 4 is: the upper conductor 40M2 does not make direct contact with the 3D-M layer 36, but through a half-via 38M. The half-via 38M penetrates only a portion of the inter-level dielectric 33, i.e. from the upper conductor 40M2 to the top surface of the 3D-M layer 36. Its depth is less than a full-via 38, which penetrates the whole inter-level dielectric 33, i.e. from the upper conductor 40M2 to the bottom conductor 30L.

FIGS. 9A-9C illustrate a preferred manufacturing process for the second preferred 3D-M/interconnect. Similar to FIGS. 5A-5E, it uses a manufacturing process compatible with dual damascene and incurs little extra manufacturing cost. First, a plurality of 3D-M pillars 36 are formed in the eM region 0EM (FIG. 9A). In this preferred embodiment, there is a 3D-M pillar 36 in each 3D-M cell. Then the inter- and intra-level dielectric 33, 35 are deposited and planarized. Different from FIG. 5C, no 3D-M pillar 36 is exposed in the eM region 0EM at this step. Finally, via and trench are formed and the upper conductor are filled in. The digital information stored in the 3D-M cells is represented by existence or absence of half-via 38M (FIGS. 9B-9C).

FIG. 10 illustrates a third preferred 3D-M/interconnect. This 3D-M/interconnect is self-aligned 3D-M pillar. The 3D-M layer 36 in the self-aligned 3D-M has a rectangular shape. One of its dimensions is equal to the width of the lower conductor 30M, the other equal to that of the upper conductor 40M2. Details on self-aligned 3D-M are disclosed in U.S. Pat. No. 6,717,222.

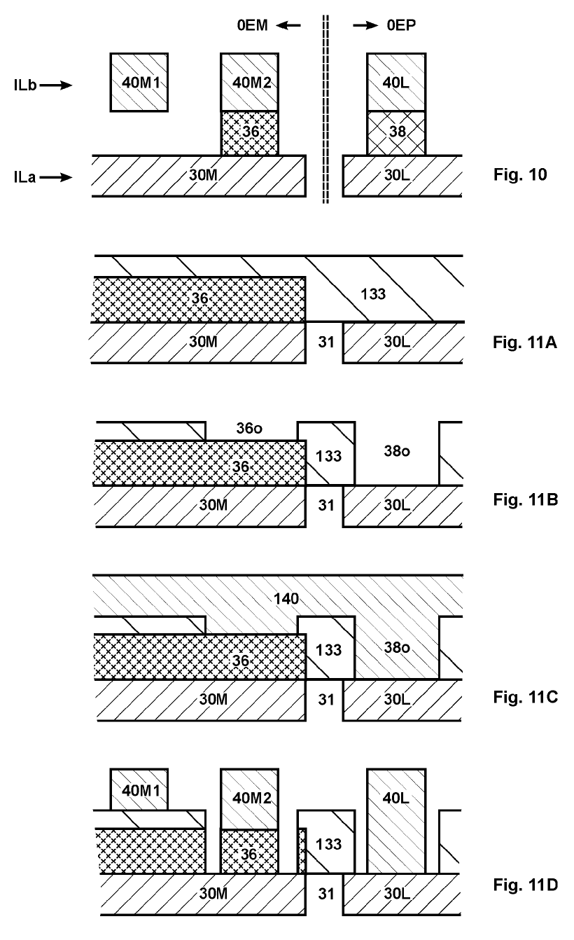

FIGS. 11A-11D illustrate a preferred manufacturing process for the third preferred 3D-M/interconnect. It comprises the following steps:

1) Deposit lower-level conductor (30M, 30L) and the 3D-M layer 36 in sequence. Then remove the 3D-M layer 36 in the eP region 0EP; etch the 3D-M layer 36 and lower-level conductor 30M in the eM region 0EM. After this, deposit and planarize a dielectric layer 133 (FIG. 11A);

2) Etch opening 36o in the eM 0EM and opening 38o in the eP 0EP (FIG. 11B). In this preferred embodiment, these openings are nF-openings (n>1). Details on the nF-openings are disclosed in U.S. Pat. No. 6,717,222;

3) Form the upper-level conductor 140 (FIG. 11C);

4) Etch the upper-level conductor 140. This step will remove some 3D-M layer 36 until the lower-level conductor 30M is exposed (FIG. 11D).

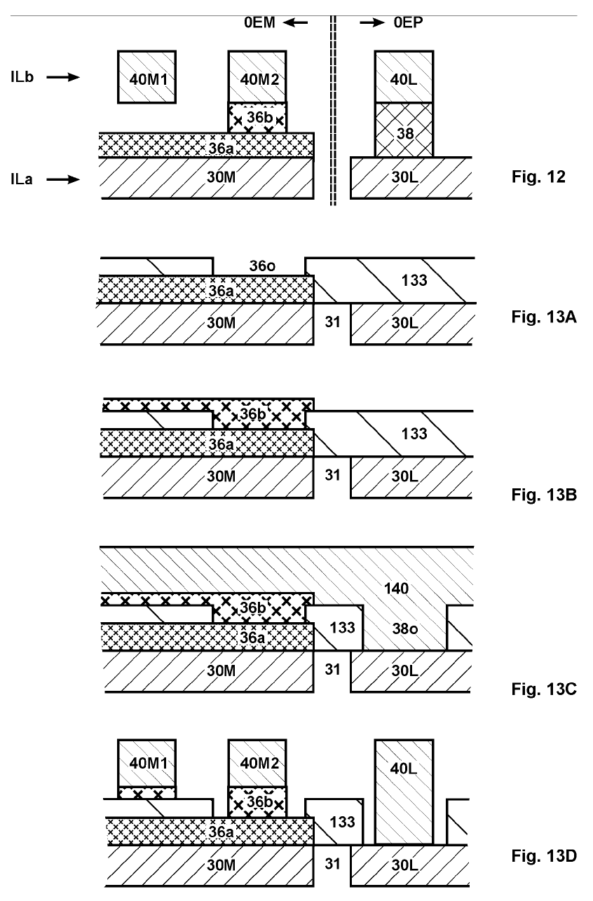

FIG. 12 illustrates a fourth preferred 3D-M/interconnect. This 3D-M/interconnect is a self-aligned natural-junction 3D-M. The 3D-M layer 36b is naturally formed at the intersection between the upper-level conductor 40M2 and lower-level conductor 30M. Details on self-aligned natural-junction 3D-M are disclosed in U.S. Pat. No. 6,717,222.

FIGS. 13A-13D illustrate a preferred manufacturing process of the fourth preferred 3D-M/interconnect. It comprises the following steps:

1) Deposit lower-level conductor (30M, 30L) and first 3D-M half-layer 36a in sequence. This 3D-M half-layer 36a could be the n-layer of FIG. 7A. Then remove the first 3D-M half-layer 36a and lower-level conductor 30M in the eM region 0EM. After this, deposit and planarize a dielectric layer 133. Form the nF-opening 36o in the eM region 0EM (FIG. 13A);

2) Form a second 3D-M half-layer 36b and remove said layer in the eP 0EP (FIG. 13B);

3) Etch and form nF-opening 38o in the eP region 0EP. Deposit the upper-level conductor 140 (FIG. 13C);

4) Etch the upper-level conductor 140 in a step similar to FIG. 11D (FIG. 13D).

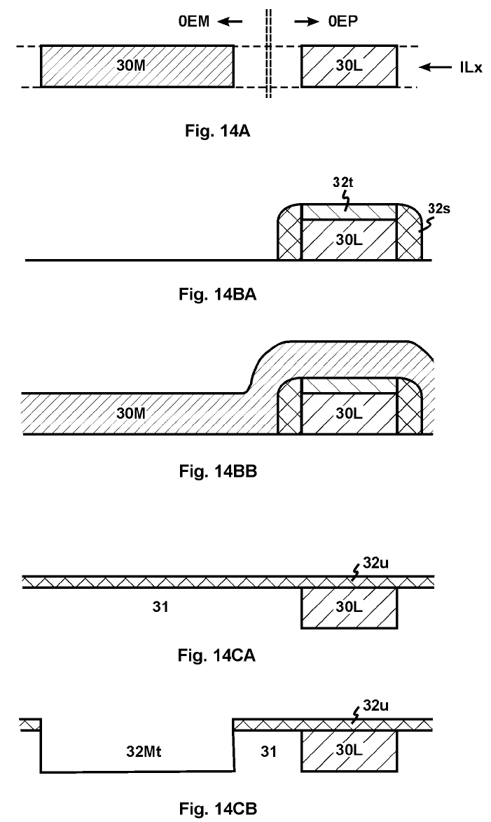

FIGS. 14A-14CB illustrate a preferred hybrid-interconnect and two preferred manufacturing processes. A hybrid-interconnect ILx comprises different conductors in different regions at the same interconnect-level. These different conductors can satisfy different requirements from different devices in these regions (e.g. conventional interconnect, 3D-M cell). For example, the eM conductor 30M (i.e. conductors used in the eM region 0EM) in FIG. 14A comprises TiSi₂, W or other conductive materials that suit the needs for the 3D-M electrodes; the eP conductor 30L (i.e. conductors used in the eP region 0EP) comprises conventional conductor such as Cu.

FIGS. 14BA-14BB illustrate a preferred manufacturing process of hybrid-interconnect. First of all, form the eP conductor 30L and deposit a dielectric 32t over it. Then form spacer layers 32s along its both sides (FIG. 14BA). This is followed by deposition of the eM conductor 30M (FIG. 14BB). After etching the eM conductor 30M, the hybrid-interconnect ILx is formed.

FIGS. 14CA-14CB illustrate another manufacturing process of hybrid-interconnect. It is compatible with damascene process. First of all, form the eP conductor 30L inside a first dielectric 31 using the damascene process. This is followed by deposition of a protective dielectric 32u (FIG. 14CA). After this, etch through the protective dielectric 32u and form trench 32Mt in the first dielectric 31 (FIG. 14CB). Finally, fill in the trench 30Mt with the eM conductor 30M and planarize it.

FIG. 15 illustrates a 3DM-SoC with half-3DM and full-3DM levels. Besides a half-3DM level 3DMA in the un-used space of the eM region 0EM, it further comprises a full-3DM level 3DMB. This full-3DM level 3DMB covers almost the whole chip, e.g. at least a portion of the eP region 0EP and at least a portion of the eM region 0EM. This full-3DM level 3DMB also comprises lower address-selection lines 50, upper address-selection lines 60 and 3D-M cells 56. With the addition of the full-3DM, 3DM-SoC can further improve its functionality.

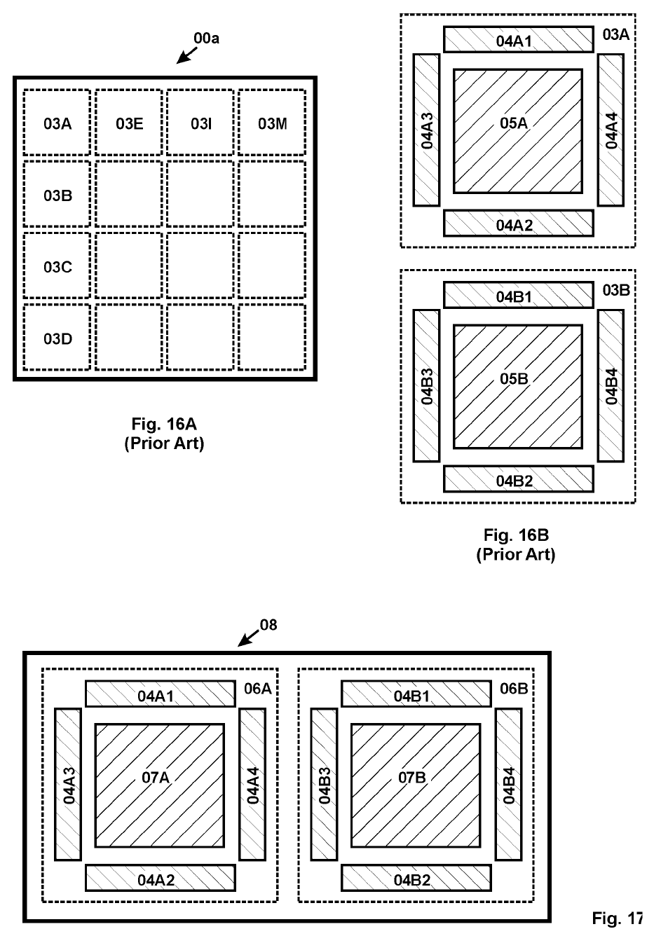

The conventional 3D-M typically uses small basic arrays. As is illustrated in FIG. 16A, this 3D-M 00a comprises a large number (e.g. 4×4=16) of small basic arrays (03A, 03B, 03C . . . ). In each basic array (e.g. 03A of FIG. 16B), its array-substrate-circuit 05A (i.e. substrate circuit underneath a basic array) is surrounded on all sides by its array-peripheral-circuit 04A1-04A4 (i.e. peripheral circuit of a basic array, e.g. decoder, sense-amp) and no portion of the array-substrate-circuit is used as the array-peripheral-circuit. Usage of small basic-arrays could pose a serious problem for system integration, because the 3D-M IC function (i.e. IC function to be integrated with the 3D-M) has to be split and laid-out into several array-substrate-circuits (e.g. into 05A, 05B of FIG. 16B). This means the previously-designed IP blocks could not be ported over and re-used.

To overcome this difficulty, the present invention discloses a 3DM-SoC with large basic array(s). As is illustrated in FIG. 17, this 3DM-SoC 08 comprises two 3D-M basic arrays 06A, 06B. Each of the array-substrate-circuit 07A, 07B underneath the 3D-M basic arrays 06A, 06B should be large enough to accommodate at least a complete IC function. Here, a complete IC function can independently implement a user function, e.g. audio-decoding, video-decoding, digital-to-analog converting, and/or decryption functions. In one preferred example, each of the array-substrate-circuit 07A, 07B can decompress the 3D-M data (decoding) and convert the decompressed data into multimedia analog signals. In other words, the output signals from the array-substrate-circuit are already multimedia analog signals, which can be readily perceived by users. Because the array-substrate-circuit is large enough to accommodate a complete IC function, previously designed IP blocks can be directly ported over and re-used therein. This can significantly simplify the 3DM-SoC design.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A three-dimensional memory system-on-a-chip (3DM-SoC), comprising:
an embedded processor using transistors in a substrate;
an embedded memory using transistors in said substrate; and
at least a half-3DM level comprising at least one three-dimensional memory (3D-M) cell, said half-3DM level located on top of at least a portion of said embedded memory, but not on top of at least another portion of said embedded processor.

2. The 3DM-SoC according to claim 1, wherein the total number of interconnect-levels in said embedded memory is less than the total number of interconnect-levels in said embedded processor.

3. The 3DM-SoC according to claim 1, wherein:
said embedded processor comprises a first and second conductors;
said embedded memory comprises a first and second address-selection lines;
said first conductor is at the same level as said first address-selection line;
said second conductor is at the same level as said second address-selection line.

4. The 3DM-SoC according to claim 1, further comprising a full-3DM level, said full-3DM level located on top of at least a portion of said embedded memory and on top of another portion of said embedded processor.

5. The 3DM-SoC according to claim 1, wherein said half-3DM level comprises electrically-programmable 3D-M cells.

6. The 3DM-SoC according to claim 5, wherein said 3D-M cells further comprises an antifuse layer.

7. The 3DM-SoC according to claim 1, wherein said half-3DM level comprises non-electrically-programmable 3D-M cells.

8. The 3DM-SoC according to claim 1, wherein said 3D-M cell further comprises a 3D-M layer, and said 3D-M layer favors current-conduction in one direction.

9. The 3DM-SoC according to claim 8, wherein said 3D-M layer further comprises a p-layer and an n-layer.

10. An integrated circuit, comprising:
a first interconnect-level;
a second interconnect-level above and adjacent to said first interconnect-level;
a via between said first and second interconnect-levels; and
a 3D-M layer between said first and second interconnect-levels.

11. The integrated circuit according to claim 10, further comprising a hybrid-interconnect having a first and second conductors with different conductive materials at the same interconnect-level.

12. The integrated circuit according to claim 11, wherein said first conductor contacts said via, and said second conductor contacts said 3D-M layer.

13. The integrated circuit according to claim 10, wherein said 3D-M layer favors current-conduction in one direction.

14. The integrated circuit according to claim 10, wherein said 3D-M layer further comprises a p-layer and an n-layer.

15. A three-dimensional memory system-on-a-chip (3DM-SoC), comprising:
at least one 3D-M basic array; and
at least one array-substrate-circuit located underneath said 3D-M basic array and surrounded by the peripheral circuits of said 3D-M basic array;
whereby said array-substrate-circuit is large enough to accommodate at least one complete IC function.

16. The 3DM-SoC according to claim 15, where said complete IC function comprises an audio-processing function, or video-processing function, or digital-to-analog converting function, or decryption function.

17. The 3DM-SoC according to claim 16, wherein said complete IC function comprises at least a multimedia-processing function and a digital-to-analog converting function.

18. The 3DM-SoC according to claim 15, wherein said 3D-M basic array comprises a plurality of 3D-M cells.

19. The 3DM-SoC according to claim 18, wherein said 3D-M cell comprises a 3D-M layer, said 3D-M layer favoring current-conduction in one direction.

20. The 3DM-SoC according to claim 19, wherein said 3D-M layer further comprises a p-layer and an n-layer.
